(19) United States
(12) Patent Application Publication
(10) Pub. No.: US 2008/0310663 A1
(43) Pub. Date: Dec. 18, 2008

(54) Microphone package adapted to semiconductor device and manufacturing method therefor

(75) Inventors: Kenichi Shirasaka, Hamamatsu-shi (JP); Seiji Hirade, Fukuroi-shi (JP); Kunihiko Mitsuoka, Iwata-shi (JP)

Correspondence Address: PILLSBURY WINTHROP SHAW PITTMAN LLP, P.O BOX 10500, McLean, VA, 22102, US

(73) Assignee: Yamaha Corporation, Hamamatsu-shi (JP)

(21) Appl. No.: 12/157,649

(22) Filed: Jun. 12, 2008

(30) Foreign Application Priority Data
Jun. 14, 2007 (JP) 2007-157673
Aug. 23, 2007 (JP) 2007-216990

(51) Int. Cl. H04R 1/00; H01L 29/84

(52) U.S. Cl. 381/355; 438/51; 257/E29.324

(57) ABSTRACT

A microphone package includes a sound detection unit, which further includes a microphone chip for detecting sound and a control circuit for controlling the microphone chip, a substrate having a mount surface for mounting the microphone chip and the control circuit and a ring-shaped side wall, which projects upwardly from the mount surface so as to surround the sound detection unit, and a cover that is arranged above the substrate so as to form a hollow cavity with the mount surface and the ring-shaped side wall of the substrate. A sound hole establishing communication between the cavity and the external space is formed in a prescribed position of the substrate or the cover, wherein a recess or a projection is formed inside of the cover. A directional regulator is formed in the housing so as to block excessive pressure variations and environmental factors from being directed to the microphone chip.

### BACKGROUND OF THE INVENTION

1. Field of the Invention

The present invention relates to microphone packages encapsulating microphone chips and semiconductor devices. The present invention also relates to semiconductor devices such as microphone chips and pressure sensor chips as well as manufacturing methods therefor.

The present application claims priority on Japanese Patent Application No. 2007-157673 and Japanese Patent Application No. 2007-216990, the contents of which are incorporated herein by reference.

2. Description of the Related Art

Conventionally, various types of silicon condenser microphones, in which semiconductor sensor chips (e.g. microphone chips) having transducers for detecting variations of pressures such as sound pressures are arranged inside of housings having sound holes, have been developed and disclosed in various documents such as Patent Document 1.

Patent Document 1: Japanese Patent Application Publication No. 2004-537182

Patent Document 1 teaches a miniature silicon condenser microphone in which a microphone chip and an LSI chip (for controlling the microphone chip) are formed on a mount surface within a housing having a hollow cavity, wherein a sound hole is formed at a prescribed position of the housing so as to ensure communication with the external space.

Helmholtz resonance may occur in the periphery of a sound hole of the housing, wherein when the resonance frequency thereof falls within the audio frequency range, the quality of sound detected by the microphone chip may be degraded.

Various environmental factors such as sunlight, liquid droplet, and dust may easily enter into the sound hole of the housing. In particular, when liquid droplets or dusts are attached to the transducer or when light is incident on the transducer, characteristics of the semiconductor sensor chip may be unexpectedly varied.

When excessive pressure variations are directly applied to the transducer via the sound hole of the housing, the transducer may be exposed to excessive stress.

Patent Document 1 teaches an environmental barrier attached to the semiconductor device so as to prevent environmental factors from being introduced into the hollow cavity of the housing via the sound hole; however, it does not reliably protect the transducer from being exposed to excessive pressure variations. In addition, the environmental barrier has a complex structure, which may be difficult to manufacture.

### SUMMARY OF THE INVENTION

It is an object of the present invention to provide a microphone package that prevents the sound quality from being degraded due to resonance frequency, thus achieving the desired audio characteristics.

It is another object of the present invention to provide a semiconductor device that is protected from environmental factors or excessive pressure variations.

It is a further object of the present invention to provide a manufacturing method of the semiconductor device.

In a first aspect of the present invention, a microphone package includes a sound detection unit, which further includes a microphone chip for detecting sound and a control circuit for controlling the microphone chip, a substrate having a mount surface for mounting the microphone chip and the control circuit and a ring-shaped side wall, which projects upwardly from the mount surface so as to surround the sound detection unit, and a cover that is arranged above the substrate so as to form a hollow cavity with the mount surface and the ring-shaped side wall of the substrate. A sound hole establishing communication between the cavity and the external space is formed at a prescribed position of the substrate or the cover, wherein a recess or a projection is formed inside of the cover.

Due to the formation of the recess or projection, it is possible to reduce the overall volume of the cavity. When the sound hole has fixed dimensions and size, the resonance frequency of the microphone package increases as the volume of the cavity decreases; hence, it is possible to easily increase the resonance frequency to be higher than the audio frequency range.

In the above, the recess or projection can be formed integrally with the cover. Herein, the recess or projection can be formed in the peripheral portion or the center portion of the cover. This makes it possible to reduce the volume of the cavity without increasing the number of parts forming the microphone package. The recess can be easily formed by partially deforming the cover; hence, it is possible to appropriately adjust the volume of the cavity.

The recess or projection can be formed in a ring shape firmly attached to the interior surface of the ring-shaped side wall. This makes it possible to easily attach the cover to the substrate by simply inserting the recess of the cover into the opening of the substrate; hence, it is possible to easily establish the prescribed positioning of the cover relative to the substrate.

The projection can be composed of a sound absorption material attached to the interior surface of the cover. In this case, sound entering into the cavity via the sound hole does not reflect at the projection; hence, it is possible to reliably prevent the microphone chip from detecting unnecessary reflection sound; thus, it is possible to further improve the sound quality of the microphone package.

The aforementioned microphone package can be modified such that the mount surface includes a reference mount surface for disposing the ring-shaped side wall and a recessed mount surface, which is lower than the reference mount surface so as to form a step difference with the reference mount surface, wherein one of the microphone chip and the control circuit, which has a lower height, is mounted on the reference mount surface, while the other of the microphone chip and the control circuit, which has a higher height, is mounted on the recessed mount surface.

In the above, it is possible for the other of the microphone chip and the control circuit, which is higher in height, to reduce its height projecting above the reference mount surface; hence, it is possible to reduce the projecting height of the ring-shaped side wall. Thus, it is possible to reduce the volume of the cavity of the microphone package. For this reason, it is possible to easily increase the resonance frequency of the microphone package to be higher than the audio frequency range. Due to the reduced projecting height of the ring-shaped side wall, it is possible to reduce the overall thickness of the microphone package.

Since the microphone package is designed to increase the resonance frequency to be higher than the audio frequency range, it is possible to achieve the desired audio characteristics while avoiding degradation of the sound quality due to the resonance frequency.

In a second aspect of the present invention, a semiconductor device includes a housing having a cavity and a sound hole communicating with the external space, a semiconductor sensor chip, which is arranged inside of the cavity and which includes a sound detector for detecting pressure variations applied thereto, and a directional regulator for blocking the pressure variations and environmental factors, which enter into the cavity via the sound hole, from being directed to the sound detector.

In the above, the directional regulator includes a projected portion, which projects inwardly into the housing and which is positioned between the sound hole and the sound detector. In addition, the directional regulator is inclined so as to gradually distance the sound hole from the semiconductor sensor chip. Furthermore, a recess is formed inwardly into the housing so that the directional regulator is formed by way of the sound hole, which is positioned at a prescribed position of the recess that does not directly face the sound detector. This makes it possible to prevent pressure variations entering into the cavity via the sound hole from being directed to the semiconductor sensor chip, wherein a part of pressure variations subjected to reflection or diffraction at the interior wall and/or the projected portion of the housing may reach the sound detector. Therefore, even when excessive pressure variations enter into the cavity of the housing, it is possible to damp them by way of reflection and diffraction; hence, it is possible to prevent excessive stress from being applied to the sound detector due to excessive pressure variations.

Even when environmental factors such as sunlight, dust, and liquid droplet unexpectedly enter into the cavity of the housing, it is possible to reliably prevent them from directly reaching the sound detector by means of the directional regulator; hence, it is possible to avoid undesired variations of characteristics of the semiconductor sensor chip due to liquid droplet, dust, and sunlight reaching the semiconductor sensor chip.

In the above, an opening is formed at a prescribed position of the housing so as to discharge pressure variations and environmental factors towards the external space, wherein the projected portion is positioned to guide pressure variations and environmental factors towards the opening of the housing. This makes it possible for at least a part of pressure variations and environmental factors to be guided towards the opening via the projected portion, whereby they are discharged to the external space of the housing via the opening. Thus, it is possible to reliably prevent excessive stress from being applied to the sound detector and to prevent characteristics of the semiconductor device from being undesirably varied.

In addition, a cut line and a fold line connected between the opposite ends of the cut line are formed to run through a cover of the housing so that a prescribed region encompassed by the cut line and the fold line is bent downwardly inside of the housing about the fold line so as to form the projected portion, wherein the periphery of the sound hole is defined by both the cut line and the fold line. Furthermore, a vibrator is formed at a prescribed position in the housing so as to vibrate in response to the pressure variations, which thus propagate into the cavity.

The vibrator is constituted of a vibrating element, which is encompassed by a cut line running through the cover of the housing at the prescribed position and an elastic film, which is attached to the surface or the backside of the housing and is positioned in connection with the vibrating element, whereby the elastic film is elastically deformed due to vibration of the vibrating element. Alternatively, the vibrator is constituted of an opening, which makes the cavity communicate with the external space, and an elastic film having an elastic deformability, which is attached to the surface or the backside of the housing so as to cover the opening.

In a third aspect of the present invention, the semiconductor device is manufactured by way of a chip mount step for mounting the semiconductor sensor chip on the mount surface of a substrate, a cover forming step for forming a cover covering the semiconductor sensor chip above the mount surface so as to form the cavity in the housing together with the substrate, a cutting forming step for forming a cut line and a fold line connecting between opposite ends of the cut line in the periphery of the sound hole running through the cover so as to define a prescribed region encompassed by the cut line and the fold line, thus forming a projected portion having an elastic deformability, which is projected inwardly into the cavity of the housing, wherein the projected portion is positioned between the sound hole and the sound detector.

In the above, the projected portion is not necessarily formed using an independent member independently of the housing; hence, it is possible to reduce the manufacturing cost of the semiconductor device by reducing the number of parts forming the housing. Since a part of the cover is simply bent to simultaneously form the sound hole and the projected portion, it is possible to improve the manufacturing efficiency of the semiconductor device.

It is possible to form a pipe having a plurality of small holes inside of the cavity of the housing, wherein a part of pressure variations entering into the pipe via the sound hole may be introduced into the cavity via the small holes, while the remaining of pressure variations is discharged towards the external space via a through-hole. Herein, pressure variations, which may reach the sound detector via the cavity, are subjected to diffraction and damping due to the small holes of the pipe. This makes it possible to prevent excessive pressure variations from being directly introduced into the cavity; hence, it is possible to prevent excessive stress from being applied to the sound detector due to excessive pressure variations.

Since environmental factors such as sunlight, dust, and liquid droplet cannot reach the sound detector via the small holes of the pipe, they cannot actually reach the sound detector: hence, it is possible to prevent characteristics of the semiconductor sensor chip from being unexpectedly varied due to environmental factors affected on the semiconductor sensor chip.

As described above, pressure variations and environmental factors entering into the cavity of the housing are regulated in direction by means of the directional regulator, by which it is possible to easily protect the sound detector of the semiconductor sensor chip from being exposed to excessive pressure variations and environmental factors.

The vibrator of the housing prevents excessive pressure variations and environmental factors from directly entering into the cavity of the housing; hence, it is possible to protect the sound detector of the semiconductor sensor chip from being exposed to excessive pressure variations and undesired environmental factors.

### BRIEF DESCRIPTION OF THE DRAWINGS

These and other objects, aspects, and embodiments of the present invention will be described in more detail with reference to the following drawings, in which:

FIG. 1 is a sectional view showing the constitution of a microphone package including a microphone chip and a control circuit inside of a housing;

FIG. 2 is a sectional view showing a first variation of the microphone package;

FIG. 3 is a sectional view showing a second variation of the microphone package;

FIG. 4 is a sectional view showing a third variation of the microphone package;

FIG. 5 is a plan view showing the layout of a microphone chip and an LSI chip included in a housing of a semiconductor device in accordance with a second embodiment of the present invention;

FIG. 6 is a sectional view taken along line A-A in FIG. 5, which shows the constitution of the semiconductor device shown in FIG. 5;

FIG. 7 is a plan view showing the layout of the microphone chip and the LSI chip included in the housing of a semiconductor device in accordance with a first variation of the second embodiment;

FIG. 8 is a sectional view taken along line B-B in FIG. 7, which shows the constitution of the semiconductor device shown in FIG. 7;

FIG. 9 is a cross-sectional view taken along line C-C in FIG. 7, which shows a sound hole and a projected portion formed in a cover of the semiconductor device shown in FIGS. 7 and 8;

FIG. 10 is a sectional view showing the constitution of a semiconductor device in accordance with a second variation of the second embodiment;

FIG. 11 is a sectional view showing the constitution of a semiconductor device in accordance with a third variation of the second embodiment;

FIG. 12 is a sectional view showing the constitution of a semiconductor device installed in an electronic device such as a cellular phone in accordance with a fourth variation of the second embodiment;

FIG. 13 is a sectional view showing the constitution of a semiconductor device installed in the electronic device in accordance with a fifth variation of the second embodiment;

FIG. 14 is a sectional view showing the constitution of a semiconductor device installed in the electronic device in accordance with a sixth variation of the second embodiment;

FIG. 15 is a sectional view showing the constitution of a semiconductor device in accordance with a seventh variation of the second embodiment;

FIG. 16 is a plan view showing the constitution of a semiconductor device in accordance with a third embodiment of the present invention;

FIG. 17 is a sectional view taken along line D-D in FIG. 16, which shows the constitution of the semiconductor device of the third embodiment;

FIG. 18 is a plan view showing a semiconductor device in accordance with a first variation of the third embodiment;

FIG. 19 is a sectional view taken along line E-E in FIG. 18, which shows the constitution of the semiconductor device of FIG. 18;

FIG. 20 is a plan view showing the constitution of a semiconductor device in accordance with a second variation of the third embodiment;

FIG. 21 is a sectional view taken along line F-F in FIG. 20, which shows the constitution of the semiconductor device of FIG. 20;

FIG. 22 is a plan view showing the constitution of a semiconductor device having a vibrating element, which is formed in a cover and is covered with an elastic film, in accordance with a fourth embodiment of the present invention;

FIG. 23 is a sectional view showing the semiconductor device of FIG. 22 installed in the housing of an electronic device;

FIG. 24 is a sectional view showing that the vibrating element of the cover vibrates in response to pressure variations;

FIG. 25 is a sectional view showing a variation of the semiconductor device in which the vibrating element of the cover is reduced in thickness; and

FIG. 26 is a sectional view showing another variation of the semiconductor device in which a sound hole of the cover is simply covered with an elastic film.

### DESCRIPTION OF THE PREFERRED EMBODIMENTS

The present invention will be described in further detail by way of examples with reference to the accompanying drawings.

### 1. First Embodiment

A first embodiment of the semiconductor device will be described with reference to FIG. 1 by way of a microphone package 1. The microphone package 1 includes a sound detection unit 5, which is encapsulated in a housing 3 having a hollow cavity S and a sound hole 3a communicating with the external space.

In the sound detection unit 5, a microphone chip 7 and a control circuit 9, both mounted on a mount surface 3b of the housing 3, are electrically connected together via a wire 11.

The microphone chip 7 is constituted of a support 13 (having an inner hole 13a running through in the thickness direction) and a sound detector 15, which is arranged to cover the inner hole 13a so as to detect variations of pressures such as sound pressures.

An electrode pad 13b joining a first end of the wire 11 is formed at a prescribed position of the support 13. The sound detector 15 is constituted of a fixed electrode 15a having a rectangular plate shape for covering the inner hole 13a of the support 13 and a diaphragm 15b, which is positioned opposite to the fixed electrode 15a with a prescribed distance therebetween so as to vibrate in response to pressure variations applied thereto. The microphone chip 7 is mounted on the mount surface 3b via a die bond material (not shown) such that the sound detector 15 is positioned opposite to the mount surface 3b of the housing 3 via the inner hole 13a.

The control circuit 9 is constituted of an LSI chip 17 (for driving and controlling the microphone chip 7) and a resin seal 19 for sealing the LSI chip 17.

The LSI chip 17 includes various circuits such as an amplifier for amplifying electric signals output from the microphone chip 7, an A/D converter for converting electric signals into digital signals, and a digital signal processor (DSP). An electrode pad 17b joining a second end of the wire 11 is formed at a prescribed position on the upper surface of the LSI chip 17. The LSI chip 17 is mounted on the mount surface 3b via the die bond material. The resin seal 19 seals the LSI chip 17 as well as the joint portion for joining the second end of the wire 11; hence, it is possible to reliably protect the LSI chip 17 and the joint portion.

In the sound detection unit 5 having the aforementioned constitution, the wire 11 having a curved loop shape connects between the microphone chip 7 and the LSI chip 17, wherein the top position of the wire 11 is the highest position among parts formed on the mount surface 3b.

The housing 3 is constituted of a substrate 21 having a box-like shape for including the microphone chip 7, the LSI chip 17, and a cover 23 for forming the cavity S with the substrate 21.

The substrate 21 is a multilayered wiring substrate composed of ceramics, wherein it is basically constituted of a bottom 25 having a plate-like shape forming the mount surface 3b of the housing 3 and a ring-shaped side wall 27, which projects upwardly from the mount surface 3b so as to surround the sound detection unit 5. The upper portion of the ring-shaped side wall 27 is higher than the top position of the wire 11.

When the substrate 21 is a multilayered wiring substrate composed of ceramics, it is produced by laminating multiple ceramic sheets having conduction paths of prescribed patterns forming wiring portions of the substrate 21. The ring-shaped side wall 27 is formed by laminating ring-shaped ceramic sheets.

The microphone chip 7 and the control circuit 9 are positioned with a prescribed distance therebetween inside of the ring-shaped side wall 27.

The cover 23, which is composed of a conductive material such as copper, is positioned to cover the sound detection unit 5 formed on the mount surface 3b of the substrate 21 and is attached to an upper end 27a of the ring-shaped side wall 27. That is, the cover 23 covers the opening of the substrate 21 so as to form the hollow cavity S.

The cover 23 defined by an exterior surface 23a and an interior surface 23b has a recess 29, which is recessed downwardly from the upper end 27a of the ring-shaped side wall 27 inside of the cavity S. The recess 29 has a ring-like shape closely attached to the interior of the ring-shaped side wall 27. The distal end of the recess 29 of the cover 23 is positioned lower than the upper surface of the LSI chip 7 but is higher than the mount surface 3b with a prescribed distance therebetween.

The positioning of the distal end of the recess 29 is not necessarily limited as shown in FIG. 1. The present embodiment is designed such that the distal end of the recess 29 of the cover 23 is positioned lower than the upper end 27a of the ring-shaped side wall 27 but is positioned between the upper end 27a of the ring-shaped side wall 27 and the upper surface of the microphone chip 7.

A peripheral portion 29a of the recess 29 is positioned along with the interior of the ring-shape side wall 27, while a center portion 29b of the recess 29 is formed in a dome-like shape so as not to come in contact with the top portion of the wire 11 arranged substantially above the center of the mount surface 3b. It is preferable that the top position of the center portion 29b of the recess 29 of the cover 23, which is positioned just above the top position of the wire 11, be positioned lower than the upper end 27a of the ring-shaped side wall 27. In other words, it is preferable that the height of the cover 23 having a dome-like shape be lowered as much as possible in conformity with the loop height of the wire 11.

The sound hole 3a of the housing 3 runs through the cover 23 in its thickness direction is positioned opposite to and just above the control circuit 9.

Next, a manufacturing method of the microphone package 1 will be described in detail.

First, a chip mount step is performed in such a way that the microphone chip 7 and the LSI chip 17 are mounted on the mount surface 3b of the substrate 21. Next, a wiring step is performed in such a way that wire bonding is performed so as to electrically connect the microphone chip 7 and the LSI chip 17 via the wire 11 and to electrically connect the LSI chip 17 and the substrate 21 together. Thereafter, a sealing step is performed in such a way that the resin seal 19 is formed to entirely seal the LSI chip 17 as well as the joint portion of the wire 11.

Before or after (or simultaneously with) the chip mount step, wiring step, and sealing step, a cover forming step is performed so as to form the cover 23.

In the cover forming step, a sound hole forming step is performed so as to form the sound hole 3a running through a planar conductive plate in its thickness direction. Then, a drawing step is performed in such a way that the conductive plate is subjected to drawing so as to form the ring-shaped recess 29, which is partially recessed but partially projected. In the ring-shaped recess 29, the peripheral portion 29a projects substantially upwards, while the center portion 29b is swelled upwardly, thus forming a dome-like shape with respect to the cover 23.

The sound hole forming step can be performed before or simultaneously with the drawing step.

After completion of the chip mount step, wiring step, sealing step, and cover forming step, a cover attaching step is performed in such a way that the cover 23 is attached to the substrate 21, thus forming the cavity S between the substrate 21 and the cover 23. This completes the production of the microphone package 1. In the cover attaching step, the recess 29 of the cover 23 is engaged in contact with the interior of the ring-shaped side wall 27, thus establishing prescribed positioning between the substrate 21 and the cover 23.

Due to the formation of the recess 29 in the cover 23, it is possible to easily reduce the volume of the cavity S in the housing 3 of the microphone package 1. Since the sound hole 3a is designed with fixed dimensions, the resonance frequency of the microphone package 1 becomes higher as the volume of the cavity S becomes smaller. Hence, it is possible to easily increase the resonance frequency to be higher than the audio frequency range. Thus, it is possible to achieve the desired audio characteristics while preventing the quality of sound detected by the microphone chip 7 from being degraded due to the resonance frequency.

Since the recess 29 is integrally formed with the cover 23, it is possible to reduce the volume of the cavity S without increasing the number of parts forming the microphone package 1. Since the recess 29 is formed by partially deforming the conductive plate forming the cover 23, it is possible to easily adjust the volume of the cavity S of the microphone package 1.

In the microphone package 1, in which the recess 29 of the cover 23 is positioned inside of the opening of the substrate 21, it is possible to firmly attach the cover 23 to the substrate 21, thus easily establishing the prescribed positioning of the cover 23 relative to the substrate 21.

Since the cover 23 has conductivity, the microphone package 1 is mounted on a circuit board (not shown) such that the cover 23 is electrically connected to a ground pattern, thus forming a shield structure blocking electromagnetic noise from entering into the cavity S via the cover 23. Thus, it is possible to reliably prevent the microphone chip 7 from suffering from erroneous operation due to electromagnetic noise.

A ground wiring electrically connected to the ground pattern of the circuit board can be incorporated into the substrate 21. In this case, a prescribed part of the ground wiring can be exposed on the interior surface of the ring-shaped side wall 27, which is brought into contact with the recess 29 of the cover 23. Since the recess 29 is pressed to the ground wiring, it is possible to electrically connect the cover 23 to the ground pattern, and it is therefore possible to easily form the shield structure.

When it is unnecessary to block the microphone chip 7 from electromagnetic noise, the cover 23 is not necessarily composed of conductive materials but can be composed of other materials such as resins.

The microphone package 1 is designed such that the substrate 21 is disposed on the mount surface 3b of the housing 3 and is equipped with the ring-shaped side wall 27 for surrounding the sound detection unit 5; hence, it is possible to reliably protect the microphone chip 7, the LSI chip 9, and the wire 11 from negative environmental factors during a time period between the chip mount step and the cover forming step.

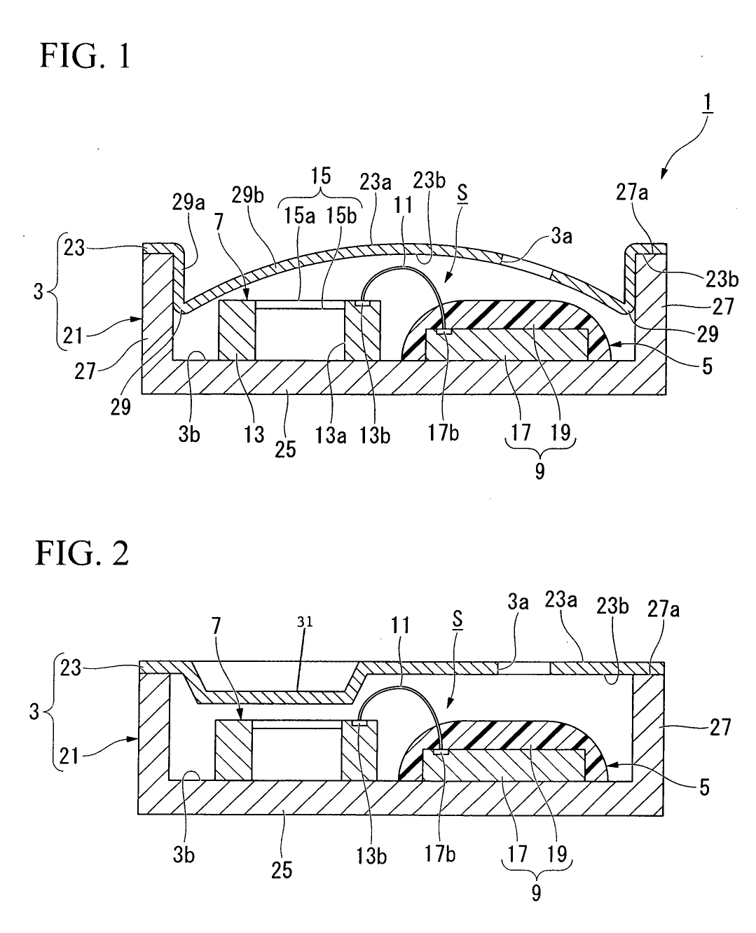

The present embodiment can be modified in a variety of ways; hence, variations will be described with reference to FIGS. 2 to 4.

The present embodiment is designed such that the recess 29 is formed in a ring shape inserted into the gap between the sound detection unit 5 and the ring-shaped side wall 27; but this is not a restriction. The present embodiment simply requires that the recess 29 project downwardly in a direction from the center portion 23b of the cover 23 to the cavity S. As shown in FIG. 2, a recess 31 is positioned to slightly depart from the ring-shaped side wall 27 and is formed opposite to the microphone chip 7 with a prescribed gap therebetween. Alternatively, the recess 31 can be positioned opposite the control circuit 9. In this case, the cover 23 is entirely formed in a plate-like shape except for the recess 31.

FIGS. 1 and 2 show that the recesses 29 and 31 are formed in the cover 23; but this is not a restriction. For example, it is possible to form a projection, which integrally projects from the center portion 23b of the cover 23 but is not recessed from the peripheral portion 23a of the cover 23. Similar to the recess 31 shown in FIG. 2, the projection can be positioned opposite the microphone chip 7 with a prescribed gap therebetween.

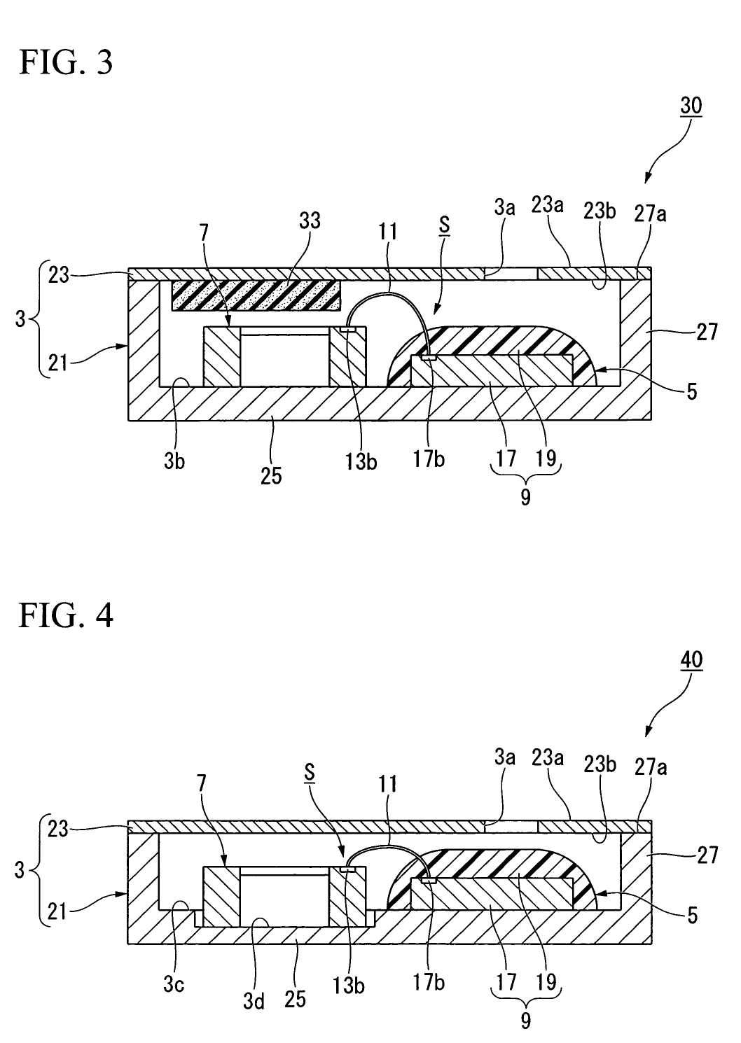

FIG. 3 shows a microphone package 30 having a projection 33, which is an independent member provided independently of the cover 23. The projection 33 is attached to the interior wall of the center portion 23b of the cover 23. In this case, the projection 33 can be composed of the same material as the cover 23 or of a different material.

When the projection 33 is composed of a sound absorption material such as a sponge rubber in the microphone package 30 shown in FIG. 3, sound entering into the cavity S via the sound hole 3a does not reflect at the projection 33; hence, it is possible to prevent the microphone chip 7 from detecting unnecessary reflection sound; thus, it is possible to improve the sound quality of the microphone package 30.

The aforementioned microphone packages 1 and 30 shown in FIGS. 1 to 3, in which the recesses 29 and 31 and the projection 33 are each formed in the cover 23, can be further modified by way of a microphone package 40 shown in FIG. 4. Herein, a reference mount surface 3c for disposing the ring-shaped side wall 27 is formed on the bottom 25 of the substrate 21, while a recessed mount surface 3d, which is lower in height than the reference mount surface 3c so as to form a step difference with the reference mount surface 3c is also formed on the bottom 25 of the substrate 21. The one of the microphone chip 7 and the control circuit 9, which has a lower height, is mounted on the reference mount surface 3c, while the other of the microphone chip 7 and the control circuit 9, which has a higher height, is mounted on the recessed mount surface 3d. In the present embodiment, the microphone chip 7 is higher in height than the control circuit 9 and is thus mounted on the recessed mount surface 3d.

In the aforementioned variation, the cover 23 can be entirely formed in a plate-like shape; alternatively, it is possible to form the aforementioned recesses 29 and 31 and the projection 33 with respect to the cover 23.

In the microphone package 40, the one of the microphone chip 7 and the control circuit 9, which is higher in height, is arranged on the recessed mount surface 3d so as to lower the height thereof relative to the reference mount surface 3c. This makes it possible to lower the loop height of the wire 11; hence, it is possible to reduce the projecting height of the ring-shaped side wall 27. As a result, it is possible to reduce the overall volume of the cavity S of the microphone package 40. Thus, similarly to the aforementioned microphone packages 1 and 30 shown in FIGS. 1 to 3, it is possible for the microphone package 40 of FIG. 4 to easily increase the resonance frequency thereof to be higher than the audio frequency range.

The microphone package 40 of FIG. 4 is advantageous in that it can reduce the projecting height of the ring-shaped side wall 27; thus, it is possible to reduce the overall thickness of the microphone package 40.

All of the present embodiment and its variations shown in FIGS. 1 to 4 are each designed such that the microphone chip 7 and the LSI chip 17 are electrically connected via the wire 11; but this is not a restriction. That is, they can be adapted to flip chip structures by which the microphone chip 7 and the LSI chip 17 are mounted on the mount surface 3b of the substrate 21.

The flip chip structure is formed by forming an electric wiring for electrically connecting the microphone chip 7 and the LSI chip 17 on the bottom 25 of the substrate 21. In this case, the microphone chip 7, the LSI chip 17, and the electric wiring of the substrate 21 collectively form a sound detection unit. When the microphone chip 7 is packaged in the flip chip structure, a recess (or a back cavity) is formed and recessed from the mount surface 3b of the substrate 21, wherein the microphone chip 7 is mounted on the mount surface 3b such that the sound detector 15 is positioned opposite to the recess.

The aforementioned structure requires that the projecting height of the ring-shaped side wall 27 of the substrate 21 above the mount surface 3b be higher than the height of the microphone chip 7 and the height of the control circuit 9.

In the above, when the height of the microphone chip 7 is highest among the heights of other parts forming the sound detection unit, it is preferable to form the recess 31 or the projection 33 in the cover 23 at a position opposite to the control circuit 9. Alternatively, it is preferable to mount the microphone chip 7 on the recessed mount surface 3d. Thus, it is possible to reduce the overall volume of the cavity S.

All of the present embodiment and its variations are designed such that the sound hole 3a of the housing 3 is formed at the prescribed position of the cover 23; but this is not a restriction. For example, the sound hole 3a can be formed at a prescribed position of the bottom 25 or the ring-shaped side wall 27 in the substrate 21.

### 2. Second Embodiment

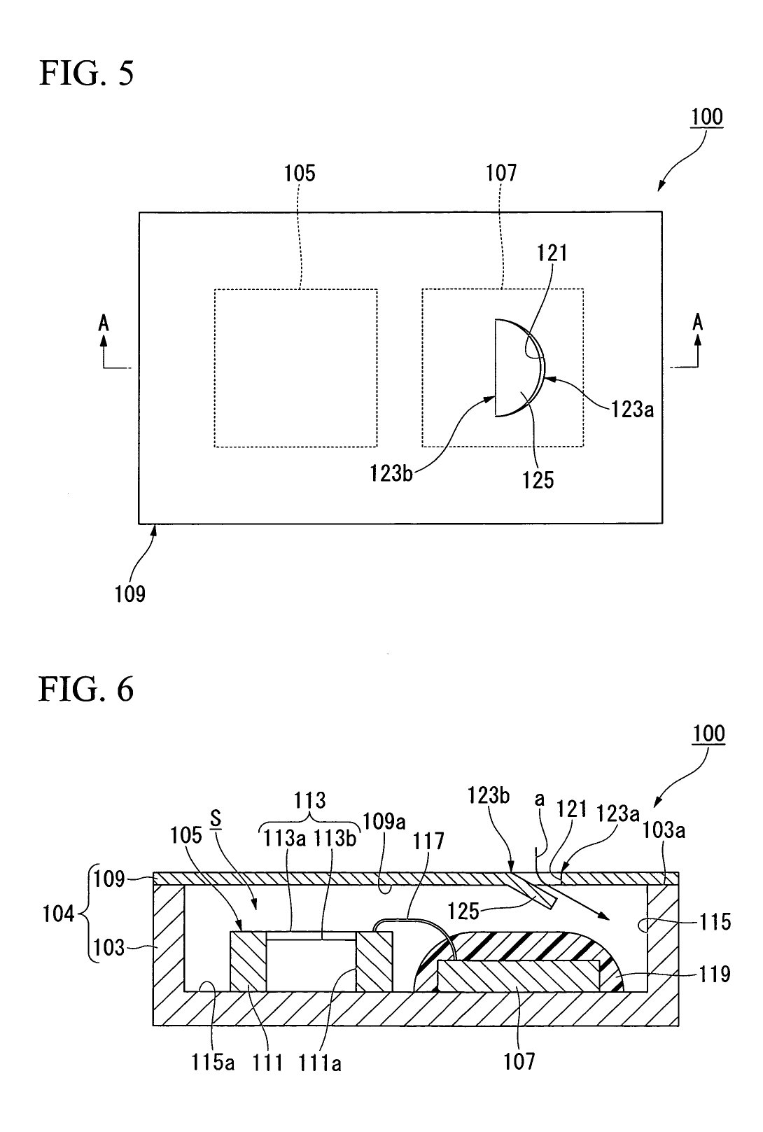

Next, a semiconductor device 100 according to a second embodiment of the present invention will be described with reference to FIGS. 5 and 6. In the semiconductor device 100, a microphone chip (or a semiconductor sensor chip) 105 and an LSI chip 107 are formed on the mount surface of a substrate 3 having a box-like shape while a cover 109 is attached to an upper end 103a of the substrate 103, thus forming a microphone package.

The microphone chip 105 is constituted of a support 111 having an inner hole 111a running through in its thickness direction and a sound detector 113, which is arranged to cover the inner hole 111a of the support 111. The sound detector 113 detects variations of pressures such as sound pressures by way of vibrations thereof. The sound detector 113 is constituted of a fixed electrode 113a having a rectangular shape for covering the inner hole 111a of the support 111 and a diaphragm 113b, which is arranged opposite to the fixed electrode 113a in a thickness direction of the support 111 with a prescribed gap therebetween and which thus vibrates due to pressure variations applied thereto.

The LSI chip 107 drives and controls the microphone chip 105, wherein it includes an amplifier for amplifying electric signals output from the microphone chip 105, an A/D converter for converting electric signals into digital signals, and a digital signal processor (DSP), for example.

The substrate 103 is a multilayered wiring substrate composed of ceramics, wherein a recess 115 having a rectangular shape in cross section is recessed from the upper end 103a. In order to form the substrate 103 as a multilayered wiring substrate composed of ceramics, multiple ceramic sheets having conduction paths of prescribed patterns (forming wirings of the substrate 103) are laminated together. The recess 115 can be formed by laminating ring-shaped ceramic sheets.

The microphone chip 105 and the LSI chip 107 are mounted on a bottom 115a (forming the mount surface) of the recess 115 via die bond materials (not shown). The microphone chip 105 is arranged such that the sound detector 113 is positioned opposite to the bottom 115a of the recess 115 via the inner hole 111a of the support 111.

The microphone chip 105 and the LSI chip 107, both of which are mounted on the bottom 115a of the recess 115, are electrically connected together via a first wire 117. The LSI chip 107 is electrically connected to a wiring portion (not shown) of the substrate 103, which is exposed on the bottom 115a of the recess 115, via a second wire (not shown). The wiring portion of the substrate 103 extends towards the peripheral portion of the substrate 103. When the semiconductor device 100 is mounted on a circuit board (not shown), the microphone chip 105 and the LSI chip 107 are electrically connected to the circuit board.

A resin seal 119, which seals the LSI chip 107 and the joint portions of the first wire 117 and the second wire, are formed above the bottom 115a of the recess 115. That is, the resin seal 119 protects the LSI chip 107 and the joint portions from negative environmental factors.

The cover 109 is formed in a rectangular shape in a plan view and is composed of a conductive material such as copper. The cover 109 is firmly attached to the upper end 103a of the substrate 103. The cover 109 is arranged to entirely cover the recess 115 above the bottom 115a of the substrate 103, the microphone chip 105, and the LSI chip 107, thus forming a cavity S including the microphone chip 105 and the LSI chip 107 with the substrate 103. A sound hole 121 is formed at a prescribed position of the cover 109 so as to run through the thickness direction thereof, thus establishing communication between the cavity S and the external space.

The cover 109 is combined with the substrate 103 so as to form a housing 104 having the sound hole 121 making the cavity S communicate with the external space. That is, the microphone chip 105 and the LSI chip 107 are arranged inside of the housing 104.

A cut line 123a having a circular-arc-like shape in plan view (see FIG. 5) is formed to run through the cover 109 in a thickness direction, and a fold line 123b having a linear shape connecting opposite ends of the cut line 123a is formed in the cover 109. A semicircular region in a plan view is defined by the cut line 123a and the fold line 123b is bent about the fold line 123b downwardly from a backside 109b of the cover 109 (forming the interior wall of the housing 104) into the cavity S towards the microphone chip 105 and the LSI chip 107. Thus, the semicircular region defined by the cut line 123a and the fold line 123b is folded about the fold line 123b so as to project downwardly into the cavity S, thus forming a projected portion 125. Thus, the sound hole 121 is formed by way of the projected portion 125 and is defined by the cut line 123a and the fold line 123b.

The projected portion 125 defined by the cut line 123a and the fold line 123b is positioned just above the LSI chip 107 sealed with the resin seal 119, wherein the fold line 123b is positioned close to the microphone chip 105 rather than the cut line 123a. That is, the projected portion 125 is positioned between the sound hole 121 and the sound detector 113.

The projected portion 125 is bent about the fold line 123b (forming the periphery of the sound hole 121) such that the distal end thereof is distanced from the sound detector 113 and is thus exposed to the external space in plan view. Therefore, even when environmental factors such as pressure variations, sunlight, dust, and liquid droplet enter into the cavity S via the sound hole 121, they are regulated to be deviated from the sound detector 113 in a direction “a” shown in FIG. 6. That is, the projected portion 125 forms a structure for preventing environmental factors from being directed to the sound detector 113 via the sound hole 121. Pressure variations entered into the cavity S are subjected to reflection and diffraction so as to reach the sound detector 113, which is thus capable of detecting them.

Next, a manufacturing method of the semiconductor device 100 will be described in detail.

In a chip mount step, the microphone chip 105 and the LSI chip 107 are fixed onto the bottom 115a of the recess 115 of the substrate 103, which is prepared in advance. In a wiring step, wire bonding is performed so as to form the wire 117 connecting between the microphone chip 105 and the LSI chip 107, and the second wire (not shown) is formed between the LSI chip 107 and the wiring portion of the substrate 103. In a sealing step, which is performed after completion of the wiring step, the resin seal 119 is formed to entirely cover the joint portions between the first wire 117 and the second wire together with the LSI chip 107.

Before or after (or simultaneously with) the chip mount step, wiring step, and sealing step, a cover forming step is performed so as to form the cover 109.

In the cover forming step, a cutout forming step is firstly performed so as to form the cut line 123a (having the semicircular shape in plan view) running through the cover 109 in the thickness direction. Next, an elastic deformation step is performed so as to form the fold line 123b (connecting the opposite ends of the cut line 123a) by way of elastic deformation of the cover 109. Due to the elastic deformation, the semicircular region defined by the cut line 123a and the fold line 123b is formed to project downwardly from the backside 109a of the cover 109, thus forming the projected portion 125. Herein, the periphery of the sound hole 121 is defined by the cut line 123a and the fold line 123b forming the projected portion 125. Specifically, it is possible to list press working as an example of the elastic deformation.

After completion of the chip mount step, wiring step, sealing step, and cover forming step, a cover fixing step is performed so as to fix the cover 109 onto the upper end 103a of the substrate 103. Thus, it is possible to complete the production of the semiconductor device 100 in which the cavity S is formed by the substrate 103 and the cover 109. In the cover fixing step, the cover 109 is fixed to the substrate 103 such that the backside 109a of the cover 109 is positioned opposite to the bottom 115a of the recess 115 while the projected portion 125 is positioned between the sound hole 121 and the sound detector 113.

Due to the formation of the projected portion 125 in the semiconductor device 100, it is possible to prevent pressure variations entering into the cavity S from being directed to the sound detector 113, wherein pressure variations are subjected to reflection and diffraction at the interior walls and the projected portion 125 in the housing 104 so as to reach the sound detector 113. Even when excessive pressure variations unexpectedly enter into the cavity S, it is possible to damp pressure variations by way of reflection and diffraction; hence, it is possible to prevent excessive stress from being applied to the sound detector 113 due to pressure variations.

Even when environmental factors such as sunlight, dust, and liquid droplet enter into the cavity S via the sound hole 121, it is possible to prevent them from directly reaching the sound detector 113 by means of the projected portion 125. Thus, it is possible to reliably avoid undesired variations of characteristics of the microphone chip 105 irrespective of light, liquid droplets, and dust unexpectedly attached to the sound detector 113.

According to the semiconductor device 100 and its manufacturing method, the projected portion 125 is formed integrally with the cover 109; thus it is possible to reduce the manufacturing cost of the semiconductor device 100 by reducing the number of parts forming the housing 104.

Since both of the sound hole 121 and the projected portion 125 can be simultaneously formed by bending the prescribed part of the cover 109, it is possible to improve the manufacturing efficiency with respect to the semiconductor device 100.

In the present embodiment, the sound hole 121 and the projected portion 125 are defined by the cut line 123a and the fold line 123b formed in the cover 109; but this is not a restriction. The present embodiment requires that the fold line 123b be formed close to the microphone chip 105 rather than the cut line 123a; hence, it is possible to form the cut line 123a and the fold line 123b in desired shapes.

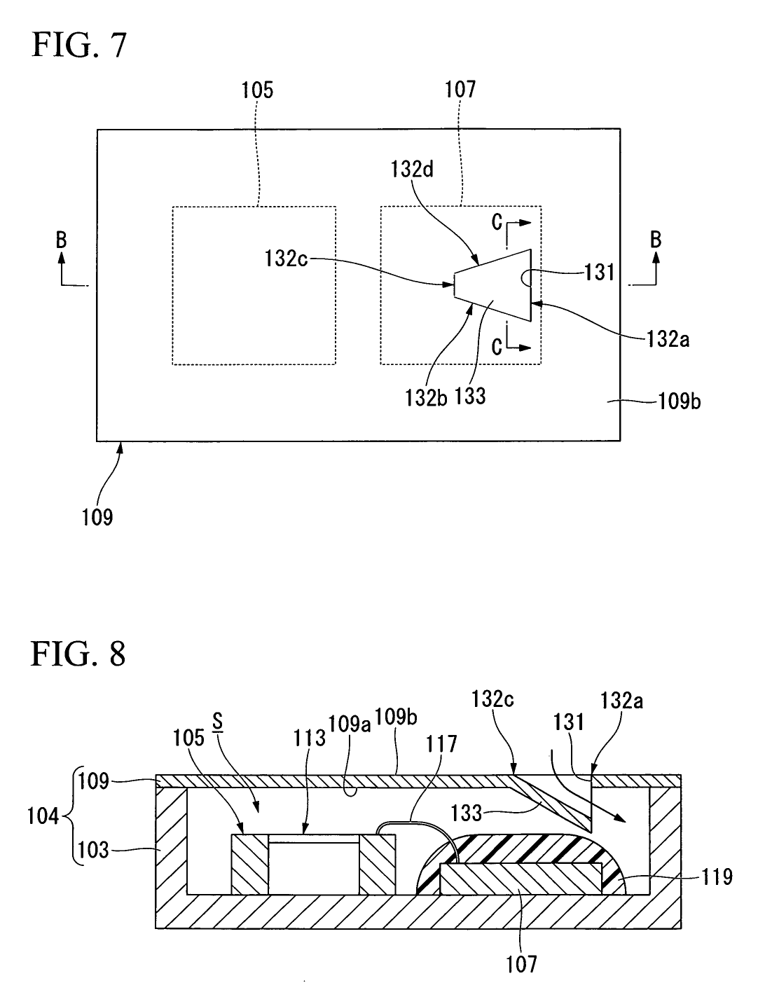

Next, variations of the semiconductor device 100 will be described with reference to FIGS. 7 to 15.

FIGS. 7 to 9 shows a first variation of the semiconductor device 100, which has a sound hole 131 and a projected portion 133, which are defined by a cut line 132a (having a linear shape in plan view) and three fold lines 132b to 132d (each having a linear shape in plan view). Herein, the sound hole 131 and the projected portion 133 are not necessarily defined by the cut line 133a and the three fold lines 132b to 132d, which can be reduced to one fold line, for example.

Similar to the present embodiment, the trapezoidal region defined by the cut line 132a and the fold lines 132b to 132d is subjected to elastic deformation so as to project downwardly from the backside 109a of the cover 109, thus forming the projected portion 133. The periphery of the sound hole 131 is defined by the projected portion 133 defined by the cut line 132a and the fold lines 132b to 132d.

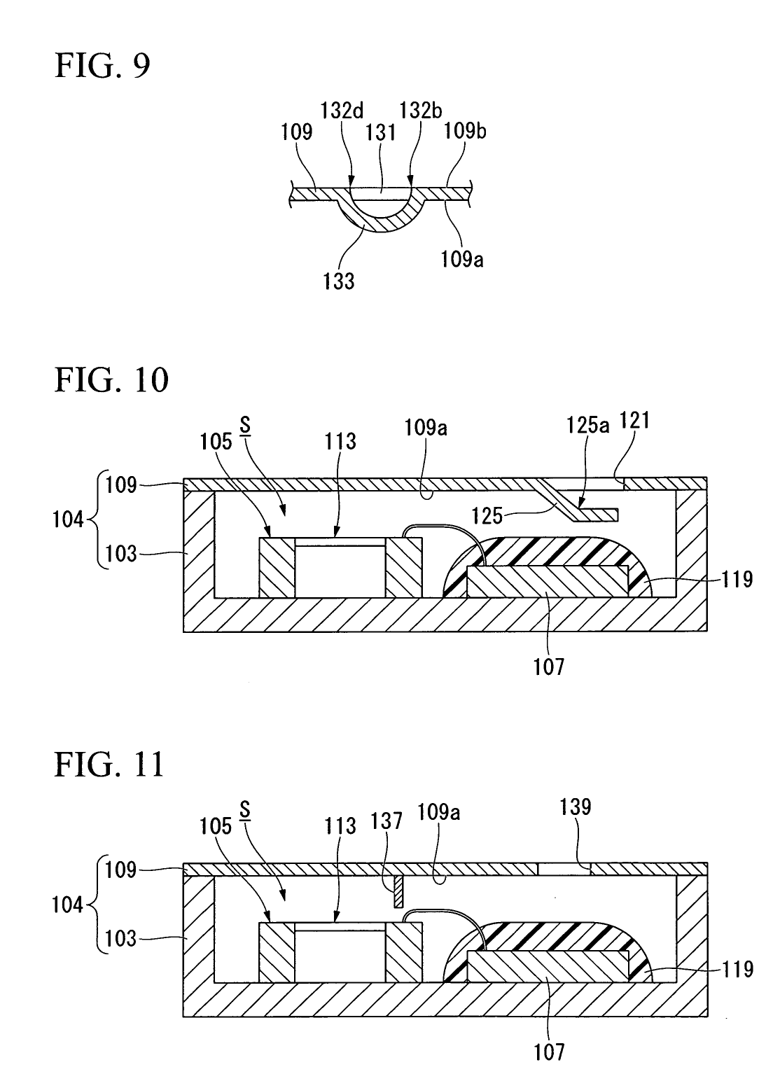

FIG. 7 is a plan view of the cover 109, in which the sound hole 131 and the projected portion 133 are each formed in a trapezoidal shape. FIG. 8 is a sectional view of the cover 109, in which the distal end of the projected portion 133 is inclined and deviated from the sound detector 113. FIG. 9 is a cross-sectional view of the projected portion 133, which has a semicircular shape in cross section. That is, the projected portion 133 is formed by recessing the trapezoidal region defined by the cut line 132a and the fold lines 132b to 132d to be lowered from the surface 109b of the cover 109.

In the present embodiment, the distal end of the projected portion 125 is inclined and deviated from the sound detector 113 and is thus exposed to the external space; but this is not a restriction. The present embodiment requires the projected portion 125 be positioned between the sound hole 121 and the sound detector 131.

FIG. 10 shows a second variation of the semiconductor device 100, in which the projected portion 125 is bent horizontally at an intermediate portion 125a lying in the inclination thereof. Alternatively, the projected portion 125 projects vertically from the backside 109a of the cover 109.

FIG. 11 shows a third variation of the semiconductor device 100, in which a projected portion 137 is composed of an independent member disposed on the backside 109a of the cover 109. In this case, it is necessary to form a sound hole 139 on the cover 109 independently of the projected portion 137.

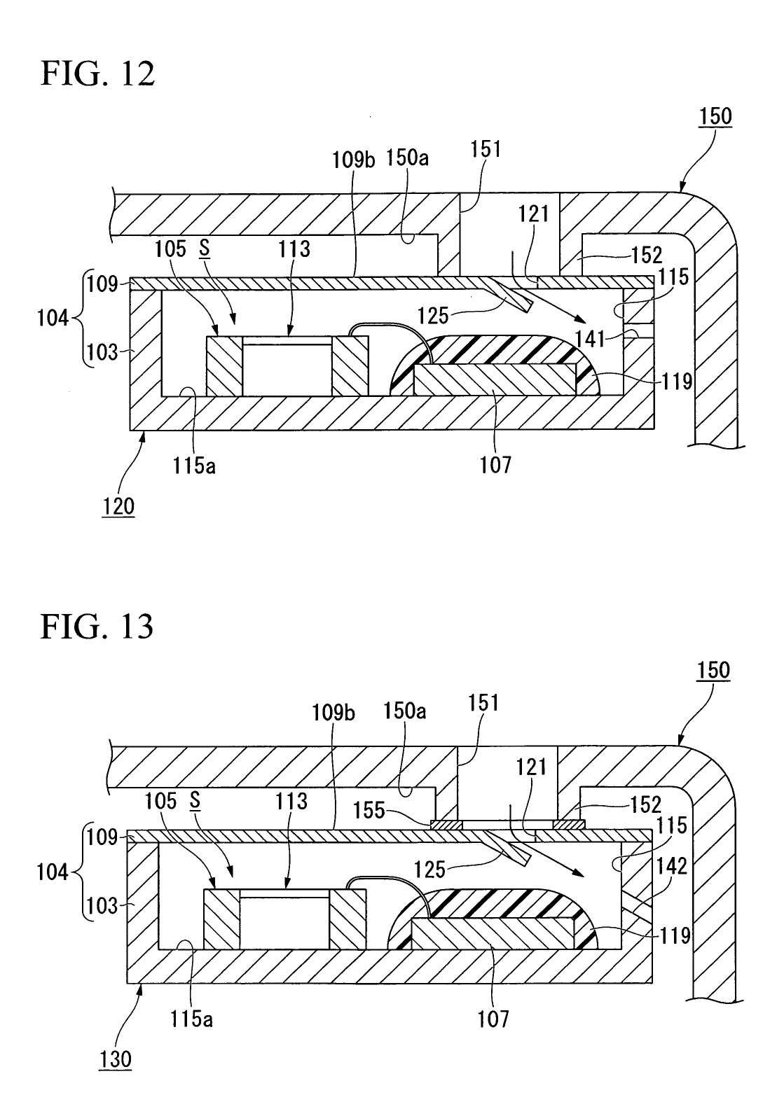

It is possible to further modify the present embodiment in such a way that openings 141, 142, and 143 (see FIGS. 12, 13, and 14) are each formed in addition to the sound hole 121 and the projected portion 125 so as to discharge at least a part of environmental factors to the external space, wherein the projected portion 125 is formed to direct at least a part of the pressure variations and the environmental factors towards each of the openings 141, 142, and 143.

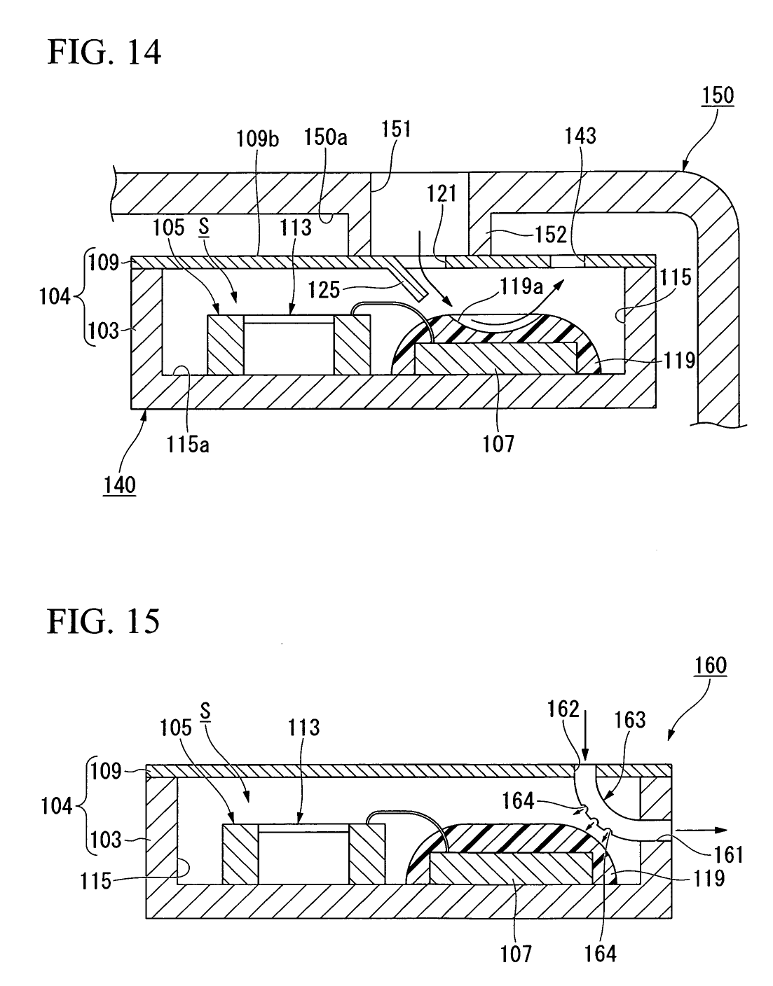

FIG. 12 is a sectional view showing a semiconductor device 120 of a fourth variation installed in a housing 150 of an electronic device such as a cellular phone, in which the opening 141 is formed at a prescribed position of a side wall of the recess 115 of the substrate 103 forming the housing 104 so as to directly receive pressure variations and environmental factors, which are regulated in propagation directions thereof by the projected portion 125. FIG. 13 is a sectional view showing a semiconductor device 130 of a fifth variation installed in the housing 150 of the electronic device, in which the opening 142 is formed at a prescribed position of the side wall of the recess 115 of the substrate 103 forming the housing 104 so as to directly receive pressure variations and environmental factors, which are regulated in propagation directions thereof by the projected portion 125. FIG. 14 is a sectional view showing a semiconductor device 140 installed in the housing 150 of the electronic device, in which the opening 143 is formed at a prescribed position of the cover 109 so as to indirectly receive pressure variations and environmental factors, which are regulated in propagation directions thereof by the projected portion 125, and is positioned forward in a propagating direction of pressure variations and environmental factors. In FIG. 14, a recess 119a is formed on a top portion of the resin seal 119 so as to direct the flow of pressure variations and environmental factors, which are initially introduced into the sound hole 121 and are regulated in direction by the projected portion 125, towards the opening 143.

The aforementioned variations are designed such that a part of the excessive pressure variations and environmental factors entering into the cavity S via the sound hole 121 is guided by the projected portion 125 and the recess 119a (formed on the upper portion of the resin seal 119) towards the openings 141 to 143, from which it is discharged towards the external space of the housing 104. Thus, it is possible to reliably avoid excessive pressure applied to the sound detector 113 and to reliably avoid undesired variations of characteristics of the microphone chip 105.

In the semiconductor device 130 of FIG. 13, the opening 142 slantingly runs through the side wall of the substrate 103 so as to make the cavity S communicate the external space. Thus, it is possible to efficiently discharge pressure variations and environmental factors, which enter along the projected portion 125 in its inclination direction (which substantially matches the slanting direction of the opening 142) via the opening 142 towards the external space.

The aforementioned semiconductor devices 120, 130, and 140 are each installed in the housing 150 of an electronic device such as a cellular phone. As shown in FIGS. 12 to 14, the sound hole 121 of the cover 109 directly faces a sound inlet hole 151 of the housing 150, which introduces sound occurring in the external space into the electronic device, while the gap between the sound hole 121 and the sound inlet hole 151 is isolated from the internal space of the housing 150. It is possible to employ various measures achieving isolation between the sound hole 121 and the sound inlet hole 151. In the semiconductor devices 120 and 140 shown in FIGS. 12 and 14, a ring-shaped projection 152, which projects inwardly from an interior surface 150a of the housing 150, is directly attached to the surface 109b of the cover 109 at a prescribed position corresponding to the periphery of the sound hole 121. In the semiconductor device 130 shown in FIG. 13, an anti-sound leak member 155, which is an independent part such as a gasket, is inserted between the ring-shaped projection 152 of the housing 150 and the cover 109 in conformity with the prescribed position corresponding to the periphery of the sound hole 121.

When the semiconductor devices 120, 130, and 140 are each installed in the housing 150 of the electronic device, the cavity S communicates with the internal space of the housing 150 via the openings 141, 142, and 143. This makes it possible to easily prevent pressure variations and environmental factors (occurring in the external space of the housing 150) from unexpectedly entering into the cavity S via the openings 141, 142, and 143.

It is possible to employ various measures, other than the openings 141, 142, and 143, for discharging pressure variations and environmental factors entering into the cavity S via the sound hole 121. FIG. 15 shows the constitution of a semiconductor device 160 in accordance with a seventh variation of the second embodiment. A through-hole 161 communicating between the cavity S and the external space is formed at a prescribed position of the side wall of the substrate 103. In addition, a pipe 163 is arranged inside of the cavity S so as to interconnect the through-hole 161 to a sound hole 162 (which is formed at a prescribed position of the cover 109 instead of the foregoing sound hole 121). A plurality of small holes 164 are formed at prescribed positions of the peripheral wall of the pipe 163 so as to make the internal space of the pipe 163 communicate with the cavity S.

In the semiconductor device 160, a part of the pressure variations entering into the pipe 163 via the sound hole 162 is forced to enter into the cavity S via the small holes 164, while the remaining pressure variations propagate through the pipe 163 and is thus discharged towards the external space of the housing 104 via the sound hole 161. That is, effective pressure variations, which enter into the cavity S so as to reach the sound detector 113, are subjected to diffraction and damping by the small holes 164 of the pipe 163. This makes it possible to effectively prevent excessive pressure variations from directly entering into the cavity S. Thus, it is possible to avoid excessive stress applied to the sound detector 113 due to excessive pressure variations. In short, the pipe 163 regulates the direction of pressure variations entering into the cavity S in the semiconductor device 160.

Other environmental factors such as sunlight, dust, and liquid droplet, which may reach the sound hole 162, cannot directly enter into the cavity S so as to reach the sound detector 113 via the small holes 164 of the pipe 163. Thus, it is possible to avoid undesired variations of characteristics of the microphone chip 105 due to light unexpectedly incident on the microphone chip 105 and/or due to dust and liquid droplets unexpectedly attached to the sound detector 113.

Similar to the semiconductor devices 120, 130, and 140 shown in FIGS. 12, 13, and 14, the semiconductor device 160 of FIG. 15 can be installed in the housing 150 of the electronic device, wherein it is possible to easily prevent pressure variations and environmental factors (occurring in the external space of the housing 150) from unexpectedly entering into the cavity S via the sound hole 161 and the small holes 164 of the pipe 163.

### 3. Third Embodiment

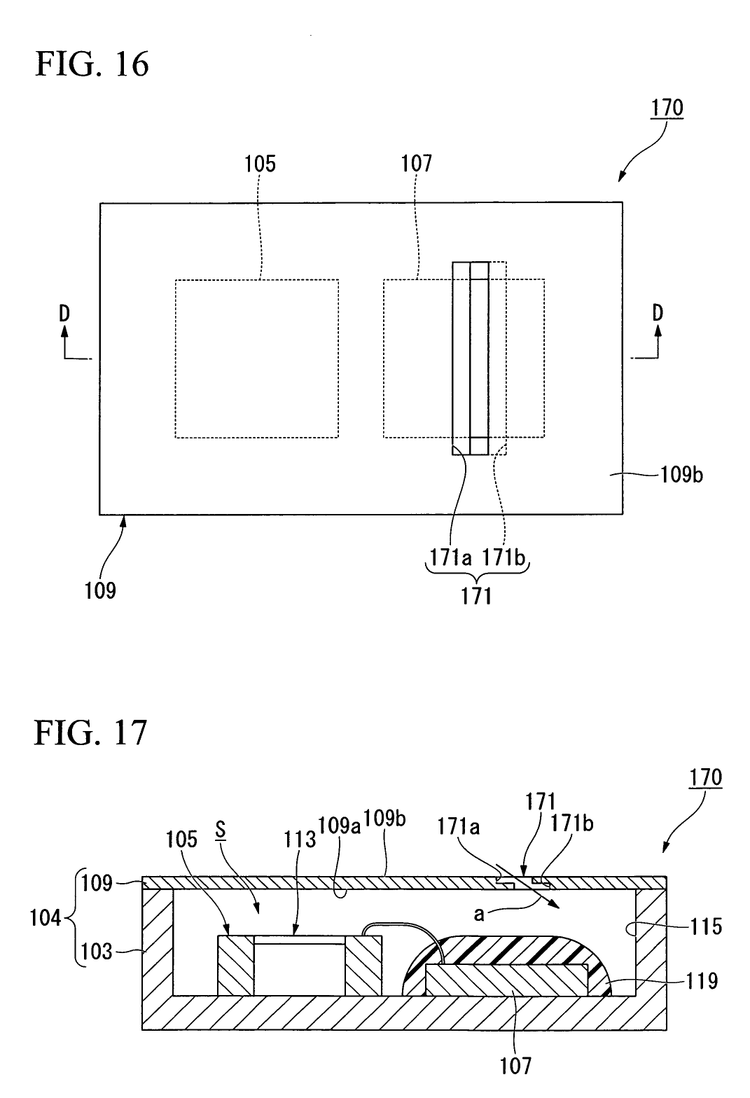

Next, a semiconductor device 170 according to a third embodiment of the present invention will be described with reference to FIGS. 16 and 17, wherein parts identical to those of the foregoing semiconductor device 100 of the second embodiment are designated by the same reference numerals; hence, the detailed descriptions thereof will be omitted.

As shown in FIGS. 16 and 17, a sound hole 171 is formed at a prescribed position of the cover 109 so as to make the cavity S communicate with the external space of the semiconductor device 170. The sound hole 171 is constituted of a first recess 171a, which is carved from the surface 109a to the backside 109b of the cover 109, and a second recess 171b, which is carved from the backside 109b to the surface 109a of the cover 109. These recesses 171a and 171b are positioned just above the LSI chip 107 sealed with the resin seal 119. The first recess 171a and the second recess 171b are mutually deviated from each other in plan view but partially overlap each other in the thickness direction of the cover 109. Specifically, the first recess 171a is positioned closer to the microphone chip 105 rather than the second recess 171b.

In other words, the sound hole 171 introduces pressure variations and environmental factors to be gradually distanced from the microphone chip 105 in a direction from the external space of the housing 104 to the cavity S.

In the above, pressure variations and environmental factors, which enter into the cavity S via the sound hole 171, are regulated in propagation directions thereof (see an arrow “a” in FIG. 17) to be distanced from the sound detector 113 by way of the sound hole 171 constituted of the first and second recesses 171a and 171b. That is, the sound hole 171 regulates the direction of pressure variations and environmental factors, which enter into the cavity S, not to directly propagate towards the sound detector 113.

In the semiconductor device 170 of the third embodiment, each of the depths of the recesses 171a and 171b may be set approximately half the thickness of the cover 109; but this is not a restriction. The present embodiment requires that each of the depths of the recesses 171a and 171b be less than the thickness of the cover 109, and the sum of the depths of the recesses 171a and 171b substantially match the thickness of the cover 109. In addition, it is possible to appropriately adjust the vertical overlapped area between the recesses 171a and 171b, which vertically overlap each other in the thickness direction of the cover 109.

The semiconductor device 170 of the third embodiment can be produced by way of the foregoing manufacturing steps adapted to the semiconductor device 100 of the second embodiment except for the cover forming step. In the third embodiment, the cover forming step may include a carving step in which the first recess 171a and the second recess 171b are subjected to half etching on the surface 109b and the backside 109a of the cover 109.

In the cover forming step, the cover 109 is attached to the upper end 103a of the substrate 103 such that the backside 109a of the cover 109 is positioned opposite to the bottom 115a of the recess 115, while the first recess 171a is positioned closer to the microphone chip 105 rather than the second recess 171b.

Similar to the semiconductor device 100 of the second embodiment, the semiconductor device 170 of the third embodiment is designed such that pressure variations and environmental factors, which may enter into the cavity S via the sound hole 171, are not directly directed towards the sound detector 113; hence, it is possible to easily protect the sound detector 113 from being exposed to excessive pressure variations and undesired environmental factors.

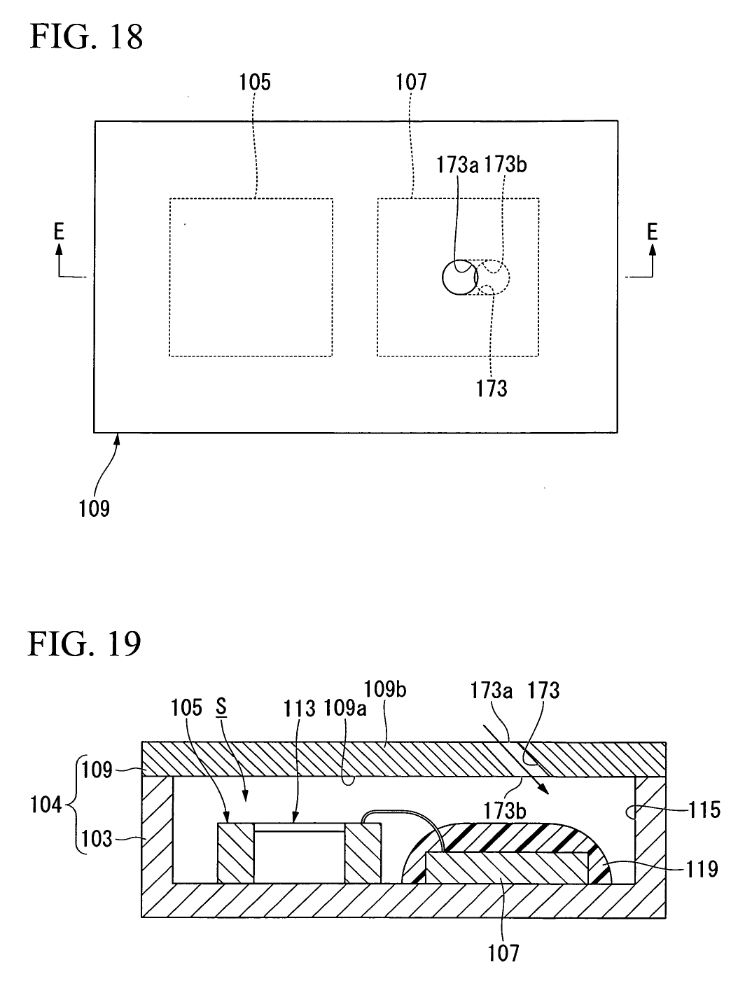

The third embodiment is designed such that the sound hole 171 is constituted of the recesses 171a and 171b, each of which has its own bottom; but this is not a restriction. That is, the third embodiment requires that the sound hole of the cover 109 be formed to slantingly run through the cover 109 in a direction gradually deviating from the external space to the cavity S. A first variation of the third embodiment will be described with reference to FIGS. 18 and 19, wherein a sound hole 173 is formed to slantingly run through the cover 109 in its thickness direction.

In the above, the sound hole 173 can be reduced in diameter or increased in inclination angle relative to the thickness direction of the cover 109. This may prevent a first opening 173a of the sound hole 173, which is formed on the surface 109b of the cover 109, from vertically overlap with a second opening 173b, which is formed on the backside 109a of the cover 109, as shown in FIG. 18.

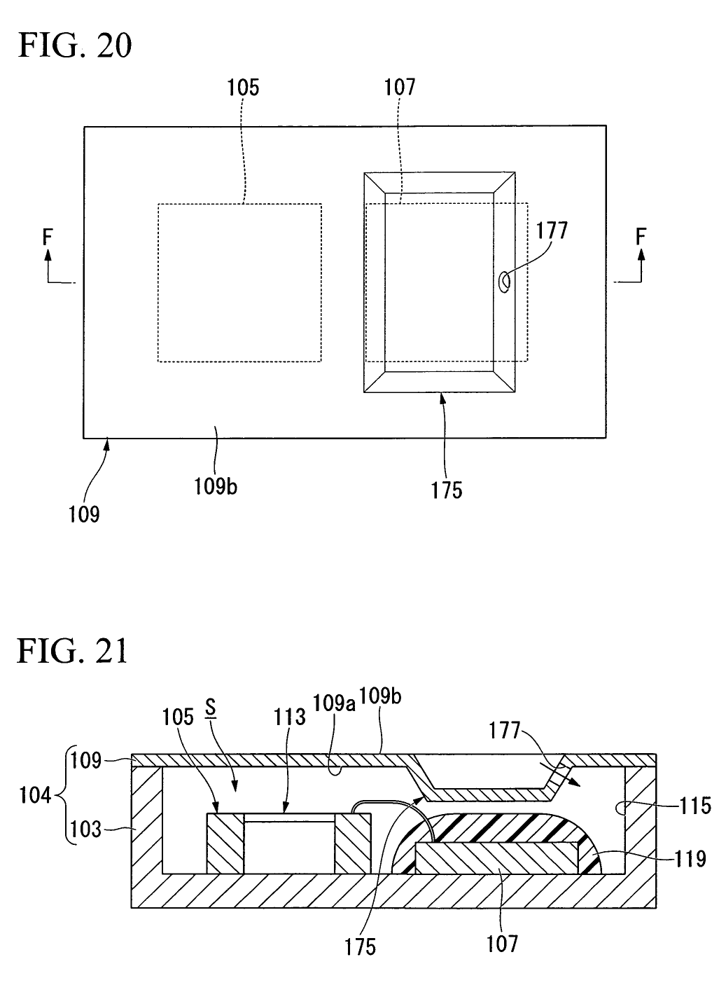

A second variation of the third embodiment will be described with reference to FIGS. 20 and 21. A recess 175, which is recessed from the surface 109b but which projects inwardly into the cavity S from the backside 109a, is formed at a prescribed position of the cover 109. The recess 175 is constituted of a side wall and a bottom, wherein a sound hole 177 is formed at a prescribed position of the side wall which is not directed to the sound detector 113.

In the semiconductor device of FIGS. 20 and 21, the sound hole 177 formed in the side wall of the recess 175 regulates the direction of pressure variations and environmental factors, which may enter into the cavity S, not to be directed to the sound detector 113. Thus, it is possible to demonstrate the foregoing effects as the second embodiment.

### 4. Fourth Embodiment

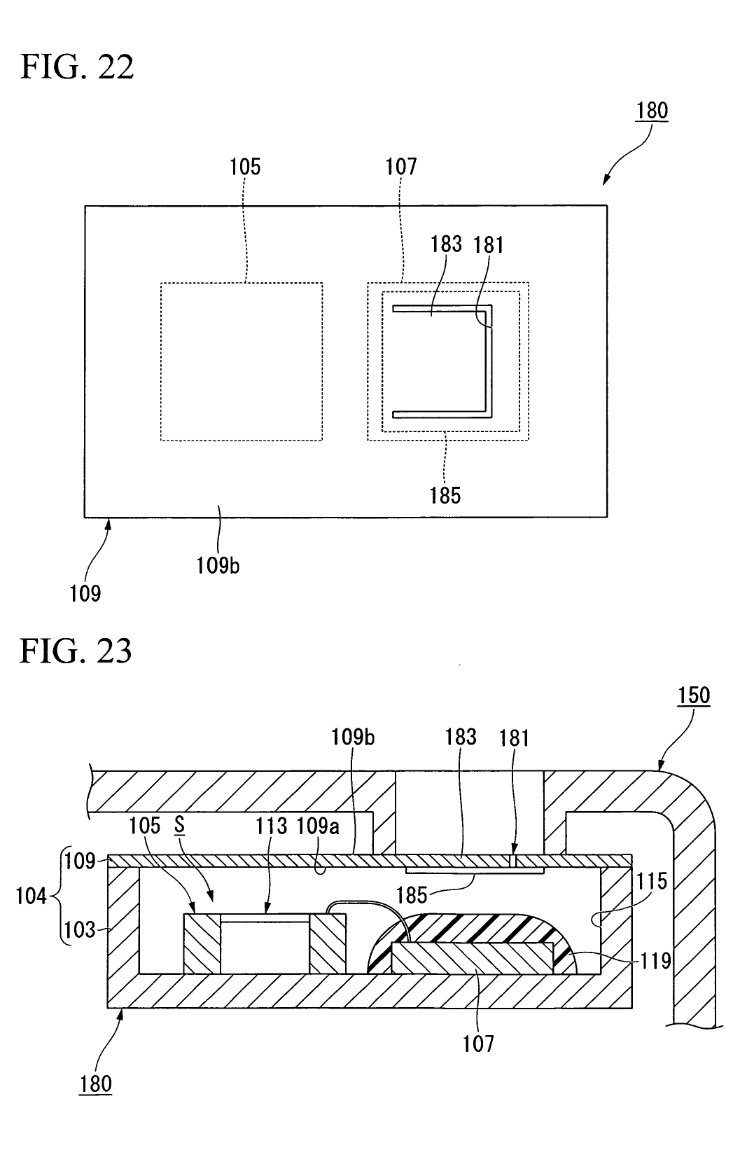

Next, a semiconductor device 180 according to a fourth embodiment of the present invention will be described with reference to FIGS. 22 to 24, wherein parts identical to those of the semiconductor device 100 are designated by the same reference numerals; hence, the detailed descriptions thereof will be omitted.

As shown in FIGS. 22 and 23, a cut line 181 having a U-shape in plan view is formed to run through the cover 109 of the semiconductor device 180. A substantially rectangular region encompassed by the cut line 181 forms a vibrating element 183 in the cover 109. The vibrating element 183 can vibrate in the thickness direction of the cover 109 except for its linear portion connected with the cover 109. An elastic film 185 composed of an elastically deformable material such as rubber is adhered to the backside 109a of the cover 109 so as to cover a prescribed area of the cover 109 including the cut line 181. That is, the cavity S of the semiconductor device 180 is sealed from the external space of the housing 104 in an airtight manner by means of the elastic film 185.

In FIG. 23, the cut line 181 of the cover 109 is positioned just above the LSI chip 107 sealed with the resin seal 119; but this is not a restriction. The present embodiment requires that the vibrating element 183 is positioned to face the cavity S; hence, the vibrating element 183 can be formed at another position of the cover 109 opposite to the microphone chip 105.

The semiconductor device 180 can be produced by way of the foregoing manufacturing steps applied to the semiconductor device 100 except for the cover forming step. That is, the cover forming step may include a cutting step in which the cut line 181 having a U-shape in plan view is formed to run through the cover 109 in its thickness direction. Then, an elastic film adhering step is performed so as to attach the elastic film 185 substantially covering the cut line 181 on the backside 109a of the cover 109.

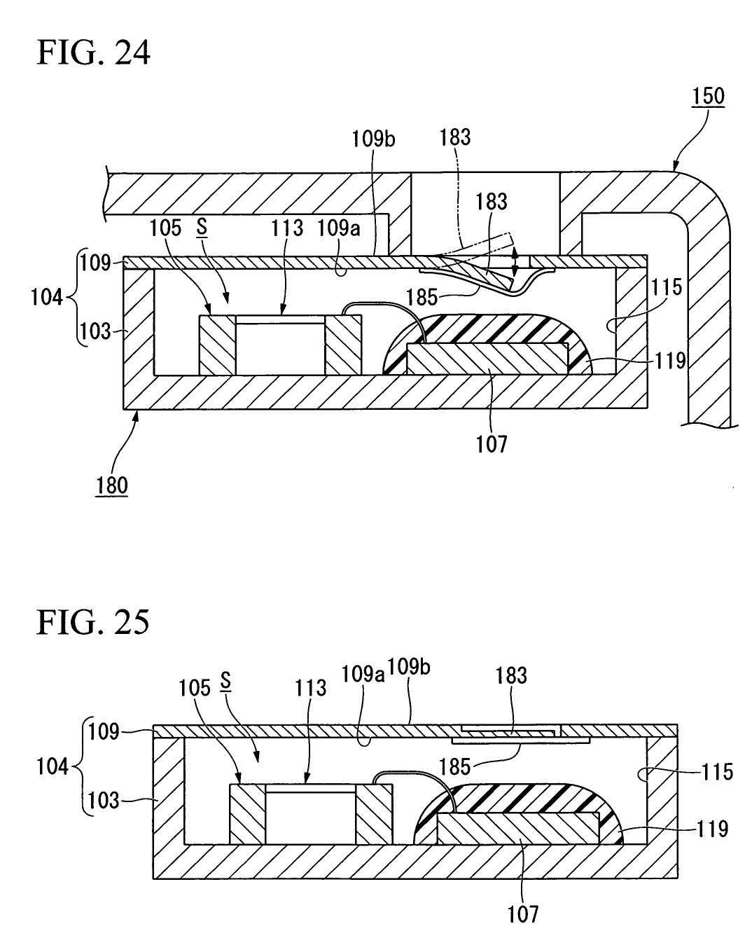

When pressure variations (occurring in the external space of the housing 104) reach the vibrating element 183 of the cover 109 of the semiconductor device 180, the elastic film 185 is elastically deformed in response to vibration of the vibrating element 183 due to pressure variations as shown in FIG. 24. Thus, pressure variations may indirectly propagate into the cavity S due to the vibration of the vibrating element 183 so as to reach the sound detector 113 of the microphone chip 105. That is, the vibrating element 183 and the elastic film 185 vibrate together in response to pressure variations occurring in the external space of the housing 104; hence, they forms a vibrator for making pressure variations propagate into the cavity S.

In the semiconductor device 180, it is possible to make pressure variations reach the sound detector 113 without forming the sound hole communicating between the cavity S and the external space of the housing 104. This makes it possible to prevent environmental factors from reaching the sound detector 113; hence, it is possible to reliably prevent environmental factors such as liquid droplets, dust, and light from reaching the sound detector 113 and to thereby avoid undesired variations of characteristics of the microphone chip 105.

When excessive pressure variations reach the exterior of the housing 104, the aforementioned vibrator damps pressure variations; hence, it is possible to prevent excessive stress from being applied to the sound detector 113 due to pressure variations. The damping rate can be adjusted by appropriately adjusting the elasticity of the vibrating element 183 and the elastic film 185.

As described above, the semiconductor device 180 is capable of easily protecting the sound detector 113 from being exposed to excessive pressure variations and environmental factors.

In the semiconductor device 180, the elastic film 185 covering the cut line 181 is adhered to the backside 109a of the cover 109 so as to seal the cavity S from the external space of the housing 104 in an airtight manner; but this is not a restriction. That is, the elastic film 185 can be adhered to the surface 109b of the cover 109.

In the present embodiment, the cut line 181 is formed in a U-shape in plan view; but this is not a restriction. The present embodiment requires that the vibrating element 183 is formed in a prescribed shape ensuring vibration thereof in the thickness direction of the cover 109.

The thickness of the vibrating element 183 is not necessarily identical to the other portion of the cover 109. For example, as shown in FIG. 25, the thickness of the vibrating element 183 can be reduced more than the other portion of the cover 109. In this case, it is possible to reduce the rigidity of the vibrating element 183 while maintaining a satisfactory rigidity with respect to the other portion of the cover 109. This improves the sensitivity of the microphone chip 105 in response to small pressure variations.

It may be possible to use half etching to reduce the thickness of the vibrating element 183, wherein half etching can be performed on the backside 109a or the surface 109b of the cover 109. It is preferable that half etching be performed on a prescribed side of the cover 109, which is opposite to the side for adhering the elastic film 185. When the elastic film 185 is adhered to the backside 109a of the cover 109, half etching is performed on the surface 109b of the cover 109.

The aforementioned vibrator is constituted of the vibrating element 183 and the elastic film 185; but this is not a restriction. The present embodiment requires that any type of vibrator, which can vibrate in response to pressure vibrations and which makes pressure vibrations propagate into the cavity S, be formed in the housing 104.

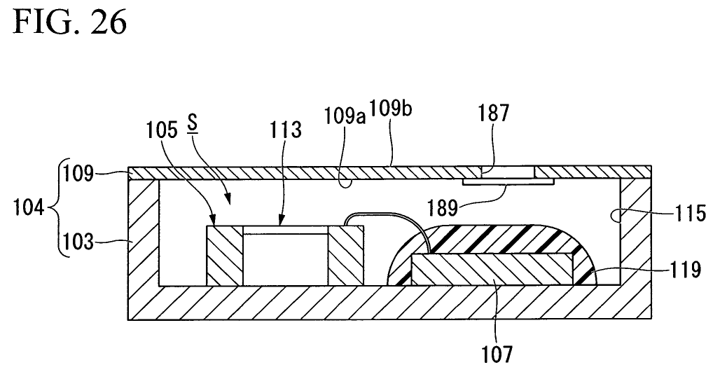

That is, the present embodiment can be modified as shown in FIG. 26 such that an opening 187 running through the thickness direction of the cover 109 is formed to make the cavity S communicate with the external space of the housing 104, wherein it is covered with an elastic film 189 (similar to the elastic film 185) that is attached to the backside 109a or the surface 109b of the cover 109. Herein, the elastic film 189 vibrates in response to pressure variations, which thus propagate into the cavity S. In this connection, the elastic film 189 forms the aforementioned vibrator, which make pressure variations propagate into the cavity S.

All the second to fourth embodiments and variations are designed such that pressure variations are introduced into the cavity S via a single sound hole and the like; but this is not a restriction. That is, it is possible to form a plurality of sound holes, which are interconnected with two or more directional regulators for regulating the direction of pressure variations and environmental factors entering into the cavity S, in the housing 104. In this case, it is possible to form a plurality of projected portions 125 and pipes 163 serving as directional regulators in the housing 104, for example.

In the housing 104 having the aforementioned structures, it is possible to make pressure variations appropriately reach the sound detector 113 without being affected by excessive pressure variations and undesired environmental factors.

All the second to fourth embodiments and variations are each designed such that the housing 104 is composed of the substrate 103 having the recess 115 and the plate-like cover 109; but this is not a restriction. They require that the housing 104 include the cavity S and be equipped with at least any one of the projected portions 125 and the sound holes 171, 173, and 175 serving as the directional regulators, and the vibrating elements 183 and the elastic films 185 and 189 serving as the vibrators. That is, the housing 104 can be constituted of the substrate 103 having a plate-like shape (not having the recess 115) and the cover 109 having a box-like shape (including a recess), for example. In addition, the substrate 103 can be equipped with at least any one of the projected portions 125 and the sound holes 171, 173, and 175 serving as the directional regulators, and the vibrating elements 183 and the elastic films 185 and 189 serving as the vibrators.

In the cover forming step, the cover 109 is mounted on the substrate 103 and is positioned above the microphone chip 105 and the LSI chip 107; but this is not a restriction. The aforementioned embodiments and variations require that the cover 109 be arranged above the mount surface of the substrate 103 so as to form the cavity S embracing the microphone chip 105.

The substrate 103 for mounting the microphone chip 105 is not necessarily limited to the multilayered wiring substrate composed of ceramics. For example, it can be formed by sealing a lead frame with a resin mold.

Lastly, the present invention is not necessarily limited to the first to fourth embodiments and variations, which can be further modified within the scope of the invention as defined in the appended claims.

What is claimed is:

1. A microphone package comprising:
a sound detection unit including a microphone chip for detecting sound and a control circuit for controlling the microphone chip;
a substrate having a mount surface for mounting the microphone chip and the control circuit and a ring-shaped side wall, which projects upwardly from the mount surface so as to surround the sound detection unit; and
a cover that is arranged above the substrate so as to form a hollow cavity with the mount surface and the ring-shaped side wall of the substrate,
wherein a sound hole establishing communication between the cavity and an external space is formed at a prescribed position of the substrate or the cover, and
wherein a recess or a projection is formed inside of the cover.

2. A microphone package according to claim 1, wherein the recess or the projection is formed integrally with the cover.

3. A microphone package according to claim 2, wherein the recess or the projection is formed in a peripheral portion or a center portion of the cover.

4. A microphone package according to claim 2, wherein the recess or the projection is formed in a ring shape firmly attached to an interior surface of the ring-shaped side wall.

5. A microphone package according to claim 1, wherein the projection is composed of a sound absorption material attached to an interior surface of the cover.

6. A microphone package comprising:
a sound detection unit including a microphone chip for detecting sound and a control circuit for controlling the microphone chip;
a substrate having a mount surface for mounting the microphone chip and the control circuit and a ring-shaped side wall, which projects upwardly from the mount surface so as to surround the sound detection unit; and
a cover that is arranged above the substrate so as to form a hollow cavity with the mount surface and the ring-shaped side wall of the substrate,
wherein the mount surface includes a reference mount surface for disposing the ring-shaped side wall and a recessed mount surface, which is lower than the reference mount surface so as to form a step difference with the reference mount surface, and
wherein one of the microphone chip and the control circuit, which is smaller in height, is mounted on the reference mount surface, while the other of the microphone chip and the control circuit, which is higher in height, is mounted on the recessed mount surface.

7. A semiconductor device comprising:
a housing having a cavity and a sound hole communicating with an external space;
a semiconductor sensor chip, which is arranged inside of the cavity and which includes a sound detector for detecting pressure variations applied thereto; and
a directional regulator for blocking the pressure variations and environmental factors, which enter into the cavity via the sound hole, from being directed to the sound detector.

8. A semiconductor device according to claim 7, wherein the directional regulator includes a projected portion, which projects inwardly of the housing, and wherein the projected portion is positioned between the sound hole and the sound detector.

9. A semiconductor device according to claim 8, wherein an opening is formed at a prescribed position of the housing so as to discharge the pressure variations and the environmental factors towards the external space, and wherein the projected portion is positioned to guide the pressure variations and the environmental factors towards the opening of the housing.

10. A semiconductor device according to claim 8, wherein a cut line and a fold line connected between opposite ends of the cut line are formed to run through a cover of the housing so that a prescribed region encompassed by the cut line and the fold line is bent downwardly inside of the housing about the fold line so as to form the projected portion, and wherein a periphery of the sound hole is defined by the cut line and the fold line.

11. A semiconductor device according to claim 7, wherein the directional regulator is inclined so as to make the sound hole be gradually distanced from the semiconductor sensor chip.

12. A semiconductor device according to claim 7, wherein a recess, which is recessed inwardly of the housing, is formed in the housing so that the directional regulator is formed by way of the sound hole, which is positioned at a prescribed position of the recess, which does not directly face the sound detector.

13. A semiconductor device according to claim 7, wherein the directional regulator is formed using a pipe, which is arranged inside of the cavity and which connects between the sound hole and a through-hole that is formed at a prescribed position of the housing so as to make the cavity communicate with the external space, and wherein a plurality of small holes are formed on the pipe to communicate with the cavity.

14. A semiconductor device comprising:
a housing having a cavity;
a semiconductor sensor chip having a sound detector, which is arranged inside of the cavity so as to detect pressure variations applied thereto; and
a vibrator, which is formed at a prescribed position of the housing so as to vibrate in response to the pressure variations, which thus propagate into the cavity.

15. A semiconductor device according to claim 14, wherein the vibrator is constituted of a vibrating element, which is encompassed by a cut line running through a cover of the housing at a prescribed position and an elastic film, which is attached to a surface or a backside of the housing and is positioned in connection with the vibrating element, whereby the elastic film is elastically deformed due to vibration of the vibrating element.

16. A semiconductor device according to claim 14, wherein the vibrator is constituted of an opening, which makes the cavity communicate with the external space, and an elastic film having an elastic deformability, which is attached to a surface or a backside of the housing so as to cover the opening.

17. A manufacturing method of a semiconductor device, in which a semiconductor sensor chip having a sound detector for detecting pressure variations is arranged inside of a cavity of a housing having a sound hole that makes the cavity communicate with an external space, comprising the steps of:
mounting the semiconductor sensor chip on a mount surface of a substrate;
arranging a cover for covering the semiconductor sensor chip above the mount surface so as to form the cavity in the housing together with the substrate; and
forming a cut line and a fold line connecting between opposite ends of the cut line in a periphery of the sound hole running through the cover so as to define a prescribed region encompassed by the cut line and the fold line, thus forming a projected portion having an elastic deformability, which is projected inwardly into the cavity of the housing,
wherein the projected portion is positioned between the sound hole and the sound detector.
